(19) United States
(12) Patent Application Publication
(10) Pub. No.: US 2015/0213905 A1
(43) Pub. Date: Jul. 30, 2015

(54) SIGNAL PROCESSING CIRCUIT AND A/D CONVERTER

(71) Applicant: Kabushiki Kaisha Toshiba, Minato-ku (JP)

(72) Inventors: Junya MATSUNO, Kawasaki (JP); Masanori FURUTA, Odawara (JP); Tetsuro ITAKURA, Nerima (JP)

(73) Assignee: KABUSHIKI KAISHA TOSHIBA, Minato-ku (JP)

(21) Appl. No.: 14/602,351

(22) Filed: Jan. 22, 2015

(30) Foreign Application Priority Data
Jan. 29, 2014 (JP) 2014-014414

(51) Int. Cl. G11C 27/02; H03M 1/12

(52) U.S. Cl. CPC G11C 27/02; H03M 1/1245

(57) ABSTRACT

A signal processing circuit according to one embodiment includes a rectifier, a holder, a controller, and a setter. The rectifier generates a rectified voltage by rectifying an input voltage in which a signal voltage is superimposed on a common-mode voltage. The holder holds a voltage. The controller controls the holder so that the holder holds a voltage according to the rectified voltage generated by the rectifier. The setter sets the voltage held by the holder to a predetermined voltage at predetermined time intervals.

### CROSS REFERENCE TO RELATED APPLICATION(S)

This application is based upon and claims the benefit of priority from the prior Japanese Patent Application No. 2014-014414, filed on Jan. 29, 2014, the entire contents of which are incorporated herein by reference.

### FIELD

Embodiments described herein relate generally to a signal processing circuit and an A/D converter.

### BACKGROUND

A pipeline A/D converter is employed in a number of LSI products as an architecture which can achieve both high speed and high resolution. The pipeline A/D converter is configured by connecting a plurality of stages for performing A/D conversion of one bit. A sampled analog signal is A/D converted bit by bit in each stage by pipeline operation. Traditionally, an operational amplifier has been used to perform A/D conversion in each stage.

Recently, a technique has been proposed which reduces power consumption of the pipeline A/D converter by using a comparator instead of the operational amplifier in each stage. However, in the above traditional technique using the comparator, since it has been necessary to charge/discharge a capacitive element with every A/D conversion in a signal processing circuit used for A/D conversion, it has been difficult to reduce enough the power consumption.

### BRIEF DESCRIPTION OF THE DRAWINGS

FIG. 1 is a block diagram of a signal processing circuit according to a first embodiment;

FIG. 2 is a circuit diagram of an example of the signal processing circuit according to the first embodiment;

FIG. 3 is a circuit diagram of another example of a controller in FIG. 2;

FIGS. 4A to 4D are explanatory diagrams of operation of the signal processing circuit according to the first embodiment;

FIGS. 5A to 5C are explanatory diagrams of the operation of the signal processing circuit according to the first embodiment;

FIG. 6 is a circuit diagram of an example of a traditional signal processing circuit;

FIGS. 7A and 7B are explanatory diagrams of operation of the traditional signal processing circuit;

FIG. 8 is an explanatory diagram of the operation of the traditional signal processing circuit;

FIG. 9 is a block diagram of another example of the signal processing circuit according to the first embodiment;

FIG. 10 is a block diagram of still another example of the signal processing circuit according to the first embodiment;

FIG. 11 is a circuit diagram of an example of a restorator in FIG. 9;

FIG. 12 is a block diagram of yet another of the signal processing circuit according to the first embodiment;

FIG. 13 is a block diagram of a signal processing circuit according to a second embodiment;

FIG. 14 is a circuit diagram of an example of the signal processing circuit according to the second embodiment;

FIG. 15 is a circuit diagram of another example of the signal processing circuit according to the second embodiment; and

FIG. 16 is a circuit diagram of an example of a signal processing circuit according to a third embodiment.

### DETAILED DESCRIPTION

Embodiments will now be explained with reference to the accompanying drawings. The present invention is not limited to the embodiments.

A signal processing circuit according to one embodiment includes a rectifier, a holder, a controller, and a setter. The rectifier generates a rectified voltage by rectifying an input voltage in which a signal voltage is superimposed on a common-mode voltage. The holder holds a voltage. The controller controls the holder so that the holder holds a voltage according to the rectified voltage generated by the rectifier. The setter sets the voltage held by the holder to a predetermined voltage at predetermined time intervals.

Embodiments of the signal processing circuit and the A/D converter will be described with reference to the drawings below.

### First Embodiment

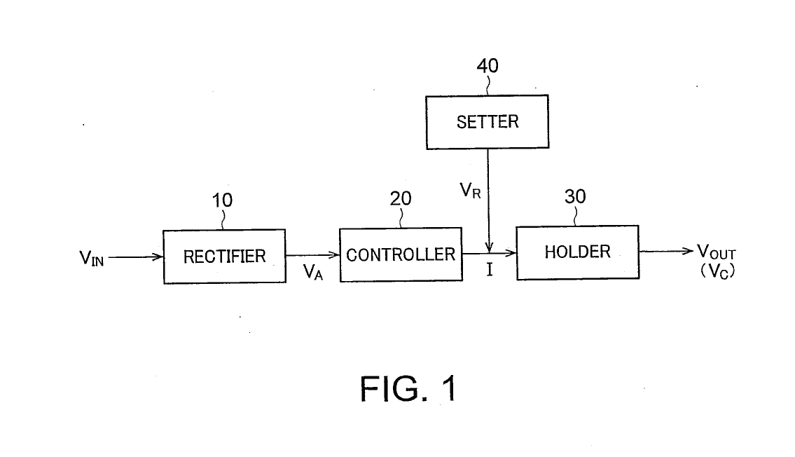

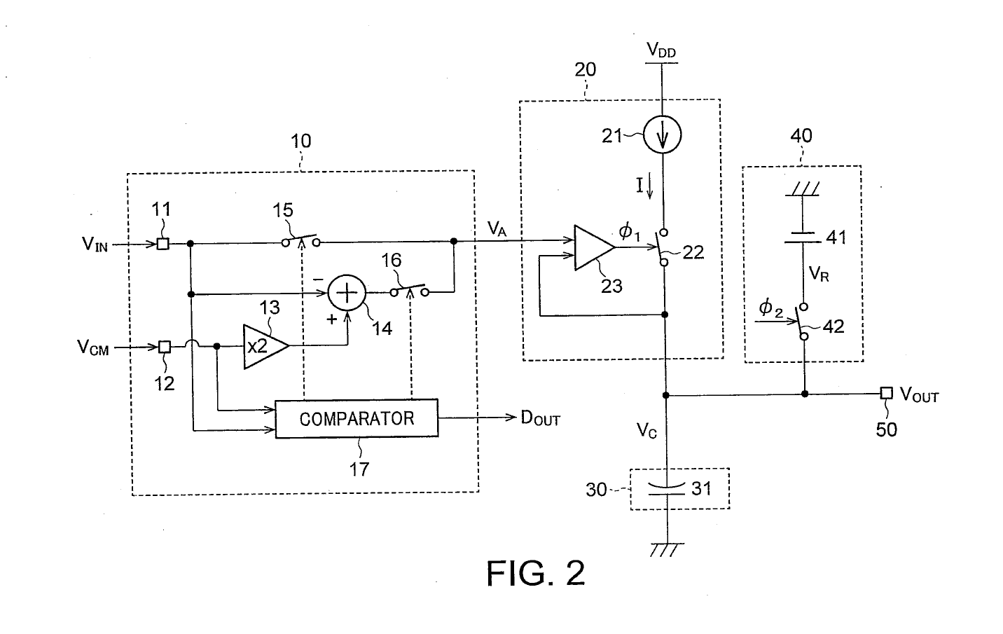

First, a signal processing circuit according to the first embodiment will be described with reference to FIGS. 1-3, 4A-4D, 5A-5C, 6, 7A-7B, and 8-12. Here, FIG. 1 is a block diagram of a function configuration of the signal processing circuit according to the present embodiment. Also, FIG. 2 is a circuit diagram of an exemplary configuration of the signal processing circuit according to the present embodiment. As shown in FIG. 1, the signal processing circuit according to the present embodiment includes a rectifier 10 for generating a rectified voltage V_{A} from an input voltage V_{IN}, a holder 30 for holding an arbitrary voltage, a controller 20 for controlling a hold voltage V_{C} held by the holder 30 based on the rectified voltage V_{A}, and a setter 40 for setting the hold voltage V_{C} to a predetermined voltage.

The input voltage V_{IN} is input to the rectifier 10. The input voltage V_{IN} is a signal in which a signal voltage V_{SIG} is superimposed on a common-mode voltage V_{CM}=V_{CM} V_{SIG}). The common-mode voltage V_{CM} is a DC component of the input voltage V_{IN}, and the signal voltage V_{SIG} is an AC component of the input voltage V_{IN}. For example, a sampled analog signal (voltage) can be exemplified as the input voltage V_{IN}.

The rectifier 10 generates the rectified voltage V_{A} which is equal to or higher than the common-mode voltage V_{CM} by rectifying the input voltage V_{IN}. More particularly, the rectifier 10 outputs the input voltage V_{IN} without rectifying it when the input voltage V_{IN} is equal to or higher than the common-mode voltage V_{CM}. Also, the rectifier 10 converts the input voltage V_{IN} lower than the common-mode voltage V_{CM} into a voltage in which an absolute value |V_{SIG}| of the signal voltage V_{SIG} is added to the common-mode voltage V_{CM} and outputs the converted voltage. Accordingly, the rectified voltage V_{A} equal to or higher than the common-mode voltage V_{CM} is output from the rectifier 10. That is, the rectified voltage V_{A} satisfies V_{A}=V_{IN}=V_{CM} V_{SIG} in a case where V_{SIG}≧0, and the rectified voltage V_{A} satisfies V_{A}=V_{CM}−V_{SIG} in a case where V_{SIG}<0. Therefore, the rectified voltage V_{A} generated by the rectifier 10 is a voltage in which the absolute value of the signal voltage V_{SIG} is added to the common-mode voltage V_{CM} (V_{A}=V_{CM}|V_{SIG}|).

As shown in FIG. 2, the rectifier 10 includes input terminals 11 and 12, an amplifier 13, a subtraction circuit 14, switches 15 and 16, and a comparator 17. The input voltage V_{IN} is input from the input terminal 11. The common-mode voltage V_{CM} is input from the input terminal 12.

The amplifier 13 is connected to the input terminal 12. The amplifier 13 amplifies two times the common-mode voltage V_{CM} input from the input terminal 12 and outputs the amplified voltage.

The subtraction circuit 14 is connected to the input terminal 11, and the input voltage V_{IN} is input to the subtraction circuit 14. Also, the subtraction circuit 14 is connected to an output side of the amplifier 13, and the twice amplified common-mode voltage V_{CM} is input to the subtraction circuit 14. The subtraction circuit 14 subtracts the input voltage V_{IN} from the twice amplified common-mode voltage V_{CM} and outputs the result. Therefore, a voltage output from the subtraction circuit 14 becomes 2V_{CM}−V_{IN}=V_{CM}−V_{SIG}.

The switch 15 (first switch) connects/opens (connects and opens) between the input terminal 11 and the controller 20. The switch 16 (second switch) connects/opens between the subtraction circuit 14 and the controller 20.

The comparator 17 is connected to input terminals 11 and 12, and each of the input voltage V_{IN} and the common-mode voltage V_{CM} is input to the comparator 17. The comparator 17 compares the magnitude of the input voltage V_{IN} with that of the common-mode voltage V_{CM} and controls opening/closing of the switches 15 and 16 based on the comparison result.

In particular, the comparator 17 turns ON the switch 15 and turns OFF the switch 16 in a case where the input voltage V_{IN} is equal to or higher than the common-mode voltage V_{CM} (V_{IN}≧V_{CM}). Accordingly, the rectified voltage V_{A} output from the rectifier 10 is the input voltage V_{IN} (V_{A}=V_{IN}=V_{CM}+V_{SIG}). Also, the comparator 17 turns OFF the switch 15 and turns ON the switch 16 in a case where the input voltage V_{IN} is lower than the common-mode voltage V_{CM} (V_{IN}<V_{CM}). Accordingly, the rectified voltage V_{A} output from the rectifier 10 is a voltage output from the subtraction circuit 14 (V_{A}=V_{CM}−V_{SIG}).

The comparator 17 outputs the comparison result between the input voltage V_{IN} and the common-mode voltage V_{CM}, that is, a signal D_{OUT} indicating magnitude relation between the input voltage V_{IN} and the common-mode voltage V_{CM}. The signal D_{OUT} output from the comparator 17 is, for example, a one-bit digital signal and is input to a restorator to be described below. A comparator can be used as the comparator 17.

In the above description, the rectifier 10 has generated the rectified voltage V_{A} which is equal to or higher than the common-mode voltage V_{CM}. However, the rectifier 10 may generate the rectified voltage V_{A} which is equal to or lower than the common-mode voltage V_{CM}. When the rectified voltage V_{A} equal to or lower than the common-mode voltage V_{CM} is generated, the rectifier 10 outputs the input voltage V_{IN} equal to or lower than the common-mode voltage V_{CM} without any processing. Also, the rectifier 10 converts the input voltage V_{IN} higher than the common-mode voltage V_{CM} into a voltage in which the absolute value |V_{SIG}| of the signal voltage V_{SIG} is subtracted from the common-mode voltage V_{CM} and outputs the converted voltage. Accordingly, the rectified voltage V_{A} equal to or lower than the common-mode voltage V_{CM} is output from the rectifier 10.

That is, when V_{SIG}<0, the rectified voltage V_{A} satisfies V_{A}=V_{IN}=V_{CM}+V_{SIG}, and when V_{SIG}≧0, the rectified voltage V_{A} satisfies V_{A}=V_{CM}−V_{SIG}. Therefore, the rectified voltage V_{A} generated by the rectifier 10 is a voltage in which the absolute value of the signal voltage V_{SIG} is subtracted from the common-mode voltage V_{CM} (V_{A}=V_{CM}−|V_{SIG}|). In the configuration of the rectifier 10 in FIG. 2, such a rectified voltage V_{A} can be generated by reversing the control of opening/closing the switches 15 and 16 by the comparator 17.

The holder 30 is a unit for holding an arbitrary voltage. The holder 30 includes a capacitive element 31 as shown in FIG. 2. The capacitive element 31 has an arbitrary impedance and can hold the arbitrary voltage between a ground voltage and a power-supply voltage V_{DD}. A side of a power supply (output side) of the capacitive element 31 is connected to the controller 20, the setter 40, and an output terminal 50 for outputting an output voltage V_{OUT} of the signal processing circuit. Therefore, the hold voltage V_{C} held by the holder 30 is output from the output terminal 50. That is, the hold voltage V_{C} coincides with the output voltage V_{OUT} (V_{C}=V_{OUT}).

The controller 20 is connected between the rectifier 10 and the holder 30. The rectified voltage V_{A} is input from the rectifier 10 to the controller 20. The controller 20 controls the holder 30 based on the rectified voltage V_{A} so that the hold voltage V_{C} becomes equal to the rectified voltage V_{A}. The controller 20 includes a current source 21, a switch 22, and a comparator 23 as shown in FIG. 2.

The current source 21 is connected to the side of the power supply (output side) of the capacitive element 31 so that a predetermined current I can be supplied to the capacitive element 31. The switch 22 (fourth switch) is provided between the current source 21 and the capacitive element 31 and connects/opens between the current source 21 and the capacitive element 31.

The rectified voltage V_{A} is input to the comparator 23 from the rectifier 10. Also, the hold voltage V_{C} is input to the comparator 23 from the holder 30. The comparator 23 compares the magnitude of the rectified voltage V_{A} with that of the hold voltage V_{C} and outputs a control signal φ₁ based on the comparison result, and then, controls opening/closing of the switch 22.

In particular, the comparator 23 turns ON the switch 22 when the rectified voltage V_{A} is higher than the hold voltage V_{C} (V_{A}>V_{C}). Accordingly, the current source 21 supplies the current I to the capacitive element 31, and the capacitive element 31 is charged. Therefore, the hold voltage V_{C} increases. Also, the comparator 23 turns OFF the switch 22 when the rectified voltage V_{A} is equal to or lower than the hold voltage V_{C} (V_{A}≦V_{C}). Accordingly, the current source 21 is opened, and the charge of the capacitive element 31 is terminated.

That is, the controller 20 increases the hold voltage V_{C} by charging the capacitive element 31 when the rectified voltage V_{A} is higher than the hold voltage V_{C}, and the controller 20 terminates the charge when the hold voltage V_{C} becomes equal to the rectified voltage V_{A}. Accordingly, the controller 20 can control the hold voltage V_{C} so as to be equal to the rectified voltage V_{A}.

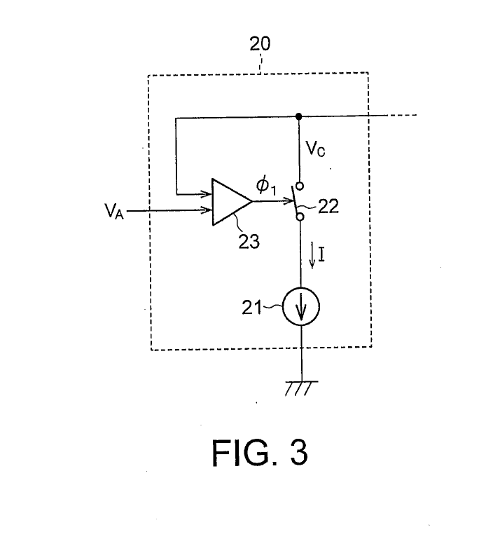

In the above description, the controller 20 is a controller of a current supply type which increases the hold voltage V_{C} by supplying the current I to the holder 30. However, the controller 20 may be a controller of a current draw type which decreases the hold voltage V_{C} by drawing the current I from the holder 30. In this case, the current source 21 is connected to a side of the ground of the capacitive element 31 so as to be able to draw a predetermined current I from the capacitive element 31 as shown in FIG. 3.

The comparator 23 in FIG. 3 turns ON the switch 22 when the rectified voltage V_{A} is lower than the hold voltage V_{C} (V_{A}<V_{C}). Accordingly, the current source 21 draws the current I from the capacitive element 31, and the capacitive element 31 is discharged. Therefore, the hold voltage V_{C} decreases. Also, the comparator 23 turns OFF the switch 22 when the rectified voltage V_{A} is equal to or higher than the hold voltage V_{C} (V_{A}≧V_{C}). Accordingly, the current source 21 is opened, and the discharge of the capacitive element 31 is terminated.

That is, the controller 20 in FIG. 3 decreases the hold voltage V_{C} by discharging the capacitive element 31 when the rectified voltage V_{A} is lower than the hold voltage V_{C}, and the controller 20 terminates the discharge when the hold voltage V_{C} becomes equal to the rectified voltage V_{A}. Accordingly, the controller 20 can control the hold voltage V_{C} so as to be equal to the rectified voltage V_{A}.

An arbitrary feedback element may be provided between the output terminal 50 and the input terminal of the comparator 23 to which the hold voltage V_{C} is input. Accordingly, signal processing similar to that of a general feedback circuit can be added to the signal processing circuit according to the present embodiment.

The setter 40 sets the hold voltage V_{C} of the holder 30 to a predetermined reset voltage V_{R}. The reset voltage V_{R} can be an arbitrary voltage equal to or lower than the common-mode voltage V_{CM} when the rectified voltage V_{A} is equal to or higher than the common-mode voltage V_{CM}. In this case, it is preferable that the reset voltage V_{R} be the common-mode voltage V_{CM} or a voltage which is slightly lower than the common-mode voltage V_{CM}. The setter 40 includes a voltage source 41 and a switch 42 as shown in FIG. 2.

The voltage source 41 is connected to the side of the power supply (output side) of the capacitive element 31 so as to be able to supply the reset voltage V_{R}. The switch 42 (third switch) is provided between the voltage source 41 and the capacitive element 31 and connects/opens between the voltage source 41 and the capacitive element 31. A control signal φ₂ input from outside controls the switch 42 to open/close at predetermined time intervals.

When the switch 42 is ON, the output side of the capacitive element 31 is connected to the voltage source 41 and the hold voltage V_{C} is set to the reset voltage V_{R}. On the other hand, when the switch 42 is OFF, the voltage source 41 is opened and the hold voltage V_{C} is controlled by the controller 20 so as to be equal to the rectified voltage V_{A}.

The reset voltage V_{R} can be an arbitrary voltage equal to or higher than the common-mode voltage V_{CM} when the rectified voltage V_{A} is equal to or lower than the common-mode voltage V_{CM}. In this case, it is preferable that the reset voltage V_{R} be the common-mode voltage V_{CM} or a voltage which is slightly higher than the common-mode voltage V_{CM}.

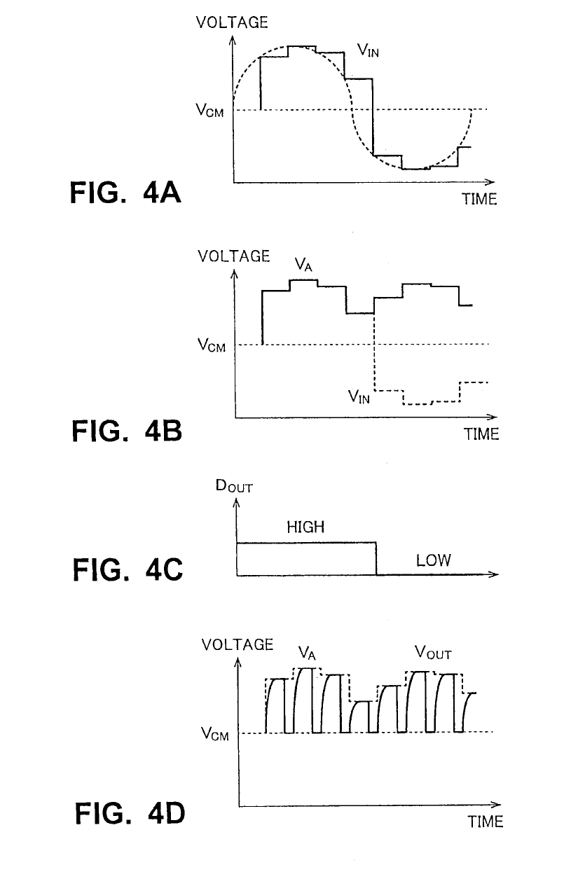

Next, operation of the signal processing circuit according to the present embodiment will be described with reference to FIGS. 4A-4D, 5A-5C, 6, 7A-7B, and 8-12. It is assumed below that the signal processing circuit be applied to each stage of the pipeline A/D converter and the rectifier 10 rectify the input voltage V_{IN} so that the rectified voltage V_{A} becomes equal to or higher than the common-mode voltage V_{CM}. Also, it is assumed that the input voltage V_{IN} be a sampled analog signal and a voltage in which the signal voltage V_{SIG} is superimposed on the common-mode voltage V_{CM}.

When an analog signal is input to the A/D converter, the analog signal is sampled at predetermined sampling intervals. Here, a dashed line indicates the analog signal and a solid line indicates the sampled analog signal in FIG. 4A. The sampled analog signal becomes a discrete voltage which changes at sampling intervals as shown in FIG. 4A. This voltage is input to the signal processing circuit as the input voltage V_{IN}.

The rectifier 10 rectifies the input voltage V_{IN} and generates the rectified voltage V_{A}. The rectified voltage V_{A} generated by the rectifier 10 is input to the controller 20. Here, a dashed line indicates the input voltage V_{IN} and a solid line indicates the rectified voltage V_{A} in FIG. 4B. As described above, the rectifier 10 rectifies the rectified voltage V_{A} so that the rectified voltage V_{A} becomes equal to or higher than the common-mode voltage V_{CM}. Therefore, the input voltage V_{IN} lower than the common-mode voltage V_{CM} is converted into an inverted voltage on the basis of the common-mode voltage V_{CM} as shown in FIG. 4B (V_{A}=V_{CM}+|V_{SIG}|).

Also, at this time, the comparator 17 of the rectifier 10 outputs the signal Dₒᵤᵣ indicating the magnitude relation between the input voltage V_{IN} and the common-mode voltage V_{CM}. The signal D_{OUT} is a one-bit digital signal in FIG. 4C. The comparator 17 outputs HIGH when V_{IN} V_{CM} and outputs LOW when V_{IN}<V_{CM}. Restoration processing of the input voltage V_{IN} using the signal D_{OUT} will be described below.

The controller 20 controls the hold voltage V_{C} of the holder 30 based on the input rectified voltage V_{A} so as to be equal to the rectified voltage V_{A}. Also, the setter 40 sets the hold voltage V_{C} of the holder 30 to the reset voltage V_{R} at the predetermined time intervals. The hold voltage V_{C} of the holder 30 is output as the output voltage \L_{OUT}.

By this operation, the signal processing circuit outputs the output voltage V_{OUT} indicated in FIG. 4D relative to the rectified voltage V_{A}. A dashed line indicates the rectified voltage V_{A} and a solid line indicates the output voltage V_{OUT} in FIG. 4D. The reset voltage V_{R} is the common-mode voltage V_{CM} in FIG. 4D. As described above, the reset voltage V_{R} can be an arbitrary voltage equal to or lower than the common-mode voltage V_{CM}. The output voltage V_{OUT} of the signal processing circuit is input to a next stage provided in the pipeline A/D converter.

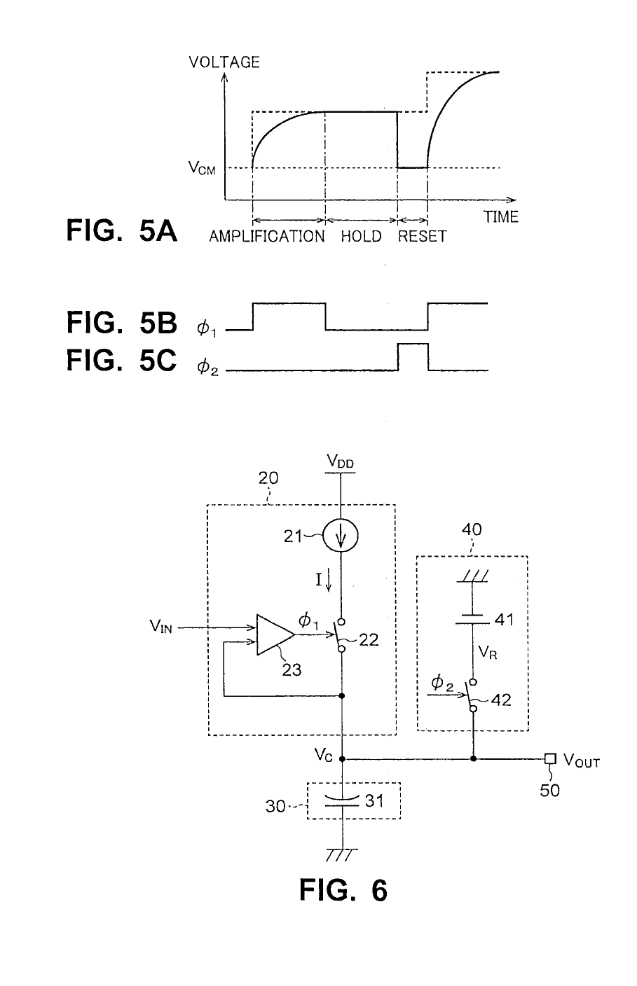

Here, operation of the controller 20, the holder 30, and the setter 40 in one cycle will be described below in detail with reference to Figs. FIGS. 5A, 5B, and 5C. The single cycle is from the input of the input voltage V_{IN} to the signal processing circuit to the input of the next input voltage V_{IN}. FIG. 5A is a partially enlarged diagram of FIG. 4D and enlarges and indicates a change of the output voltage V_{OUT} (hold voltage V_{C}) from when the input voltage V_{IN} is input to when the next input voltage V_{IN} is input. FIGS. 5B and 5C indicate states of the control signals φ₁ and φ₂ respectively, at each timing in FIG. 5A.

As shown in FIG. 5A, a period of one cycle from the input of the input voltage V_{IN} to the input of the next input voltage V_{IN} includes an amplification phase, a hold phase, and a reset phase. The amplification phase is a period from when the input voltage V_{IN} is input to when the output voltage V_{OUT} becomes equal to the rectified voltage V_{A}. The hold phase is a period from when the output voltage V_{OUT} becomes equal to the rectified voltage V_{A} to when the output voltage V_{OUT} is set to the reset voltage V_{R} (=V_{CM}). The reset phase is a period from when the output voltage V_{OUT} is set to the reset voltage V_{R} to when the next input voltage V_{IN} is input.

First, the amplification phase will be described. When the input voltage V_{IN} is input to the signal processing circuit, the rectifier 10 generates the rectified voltage V_{A} and the rectified voltage V_{A} is input to the controller 20. As shown in FIGS. 5B and 5C, the control signal φ₁ is ON and the control signal φ₂ is OFF in the amplification phase. That is, the switch 22 of the controller 20 is ON, and the switch 42 of the setter 40 is OFF.

Accordingly, the controller 20 supplies the current I from the current source 21 to the capacitive element 31 and controls the hold voltage V_{C} so as to be equal to the rectified voltage V_{A}. When the hold voltage V_{C} becomes equal to the rectified voltage V_{A}, the comparator 23 turns OFF the control signal φ₁ and turns OFF the switch 22. Accordingly, the output voltage V_{OUT} increases from the reset voltage V_{R} to the rectified voltage V_{A} in the amplification phase.

Next, the hold phase will be described. Both the control signals φ₁ and φ₂ are OFF in the hold phase. That is, the switch 22 of the controller 20 and the switch 42 of the setter 40 are OFF. Therefore, the holder 30 holds the hold voltage V_{C} (=V_{A}) controlled in the amplification phase. Accordingly, the rectified voltage V_{A} is output as the output voltage V_{OUT} during the hold phase.

Further, the reset phase will be described. The control signal becomes ON after a predetermined time from when the input voltage V_{IN} is input to the signal processing circuit. Since the predetermined time is set so that the control signal φ₂ is turned ON after the control signal φ₁ is turned OFF, the control signal φ₁ is OFF and the control signal φ₂ is ON in the hold phase. That is, the switch 22 of the controller 20 is OFF, and the switch 42 of the setter 40 is ON. Therefore, the hold voltage V_{C} of the holder 30 is set to the reset voltage V_{R}. Accordingly, the reset voltage V_{R} is output as the output voltage V_{OUT} during the reset phase.

After a predetermined time from when the control signal φ₂ is turned ON, the control signal φ₂ is turned OFF. A timing when the control signal φ₂ is turned OFF is synchronized with a timing when the next input voltage V_{IN} is input to the signal processing circuit. When the control signal φ₂ is turned OFF, the above-mentioned amplification phase starts again. That is, at a start time point of the amplification phase, the hold voltage V_{C} is set to the reset voltage V_{R}.

By repeating the above cycle, the signal processing circuit outputs the output voltage V_{OUT} as indicated in FIG. 4D. At this time, in the signal processing circuit, the current is consumed in order to charge the capacitive element 31 from the reset voltage V_{R} to the rectified voltage V_{A}. When it is assumed that the reset voltage V_{R} be the common-mode voltage V_{CM}, a current value of the current source 21 be I, the signal voltage be V_{SIG}, and the time of the amplification phase be T_{A}, a charge voltage of the capacitive element 31 is as follows.

$${V}_{SIG} = \frac{1}{C} {\int }_{0}^{{τ}_{A}} l d t \qquad [ formula 1 ]$$

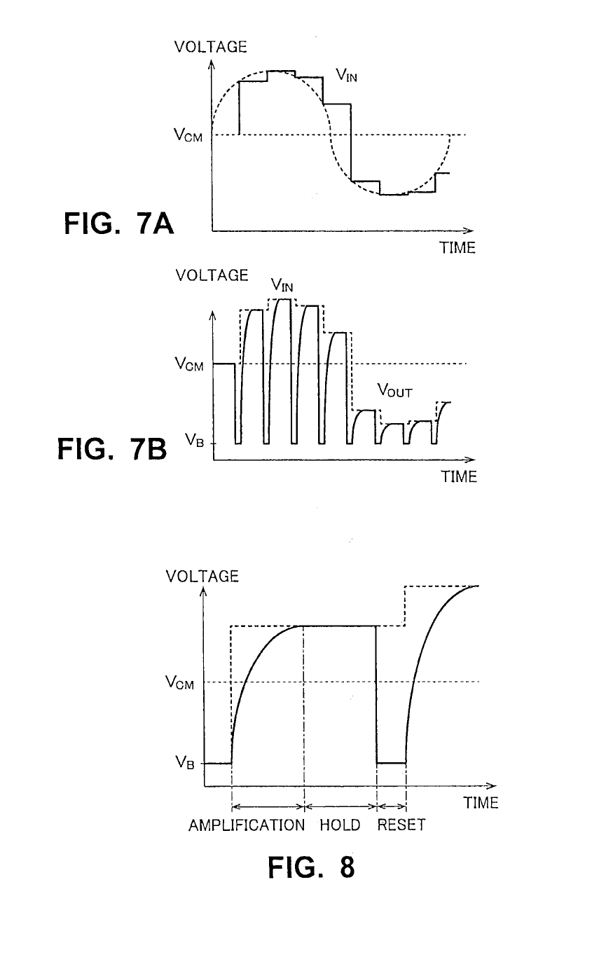

When it is assumed that the maximum amplitude of the signal voltage V_{SIG} be V_{SIGMAX} (=max |V_{SIG}|), the maximum current consumption per cycle becomes I=max (C×(V_{IN}−V_{CM}))/T=C×V_{SIGMAX}/T_{A}.

Whereas, the traditional signal processing circuit shown in FIG. 6 does not include the rectifier 10 of the present embodiment. Therefore, the input voltage V_{IN} as indicated in FIG. 7A is input to the controller 20. The minimum value of the input voltage V_{IN} becomes V_{CM}−V_{SIGMAX}, and the maximum value of the input voltage V_{IN} becomes V_{CM}+V_{SIGMAX}. In such a signal processing circuit, the reset voltage of the setter 40 is set to a voltage V_{B} equal to or lowers than V_{CM}−V_{SIGMAX} (V_{B}≦V_{CM}−V_{SIGMAX}) as shown in FIG. 7B. When the reset voltage V_{B} is V_{CM}−V_{SIGMAX}, the maximum current consumption per cycle becomes I=max (C×(V_{IN}−V_{B}))/T_{A}=2×C×V_{SIGMAX}/T_{A}.

As described above, compared with the traditional signal processing circuit, the signal processing circuit according to the present embodiment reduces the power consumption when the capacitive element 31 is charged/discharged. For example, the maximum current consumption is approximately half of that of the traditional signal processing circuit as described above. Therefore, the power consumption of the signal processing circuit can be reduced according to the present embodiment. Also, since a dynamic range of the comparator 23 can be reduced, the signal processing circuit according to the present embodiment can easily cope with voltage reduction according to miniaturization of manufacturing process.

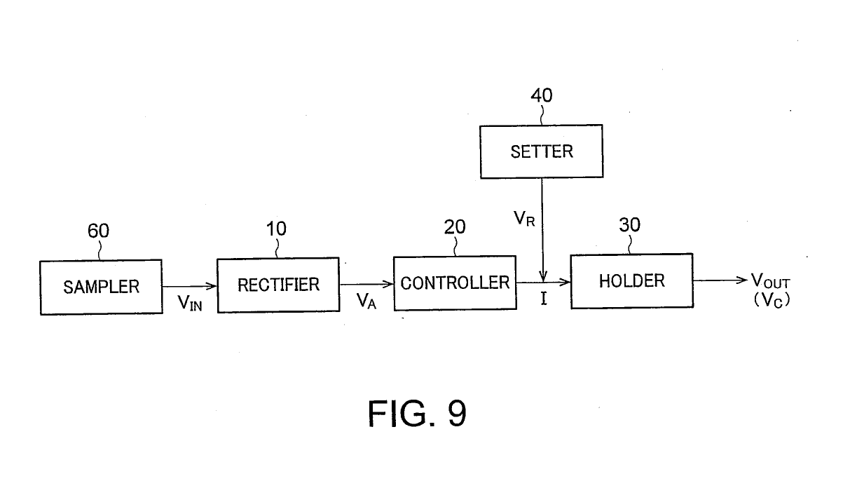

The signal processing circuit according to the present embodiment may include a sampler 60 as shown in FIG. 9. The sampler 60 is provided on the input side of the rectifier 10, and the analog signal is input to the sampler 60. The sampler 60 samples the analog signal at predetermined sampling intervals. The analog signal sampled by the sampler 60 is input to the rectifier 10 as the input voltage V_{IN}.

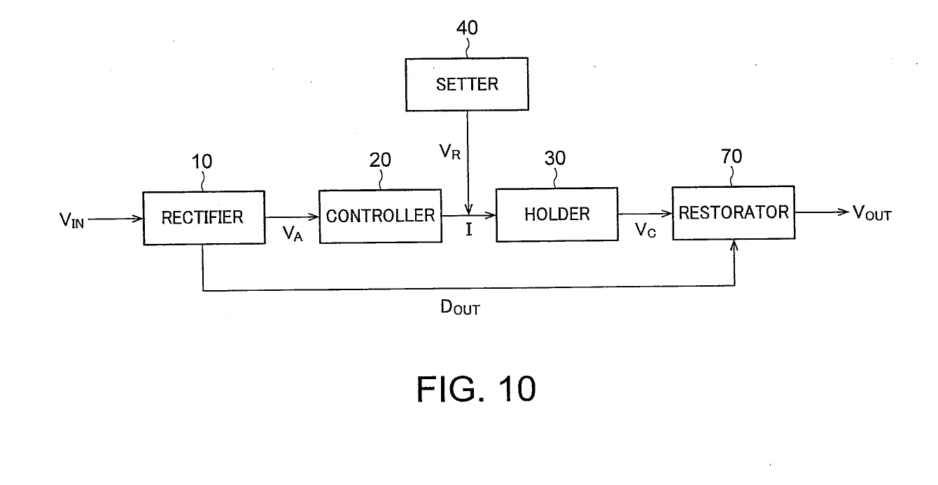

Also, the signal processing circuit according to the present embodiment may include a restorator 70 as shown in FIG. 10. The restorator 70 is provided on the output side of the holder 30, and the hold voltage V_{C} is input from the holder 30 to the restorator 70. The digital signal D_{OUT} is input from the rectifier 10 to the restorator 70. The restorator 70 restores the hold voltage V_{C} to the input voltage V_{IN} based on the digital signal D_{OUT}.

For example, when the rectified voltage V_{A} generated by the rectifier 10 satisfies V_{A}=V_{CM}+|V_{SIG}|, the restorator 70 outputs the hold voltage V_{C} as the output voltage V_{OUT} without restoring it when the digital signal D_{OUT} indicating V_{IN}≧V_{CM} is input (V_{OUT}=V_{CM}|V_{SIG}|). On the other hand, when the digital signal D_{OUT} indicating V_{IN}<V_{CM} is input to the restorator 70, the restorator 70 inverts the hold voltage V_{C} relative to the common-mode voltage V_{CM}. Then, the restorator 70 outputs the inverted voltage as the output voltage V_{OUT} (V_{OUT}=V_{CM}−|V_{SIG}|). Accordingly, the input voltage V_{IN} is restored.

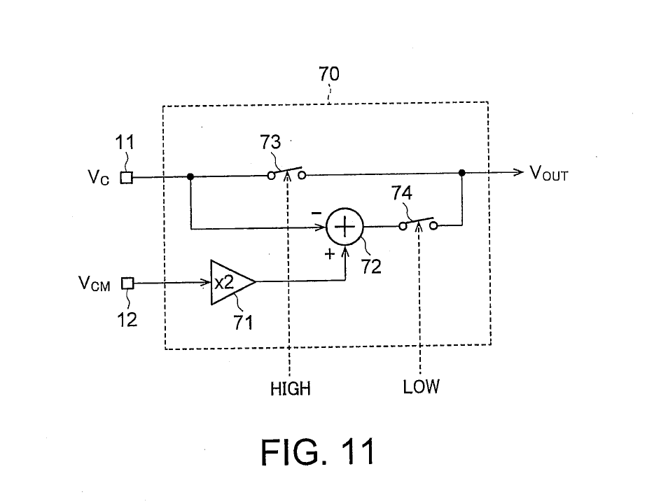

As shown in FIG. 11, the restorator 70 can include an amplifier 71 for amplifying twice the common-mode voltage V_{CM}, a subtraction circuit 72 for subtracting the hold voltage V_{C} from the output by the amplifier 71, and switches 73 and 74. The switches 73 and 74 are controlled by the digital signal D_{OUT}. The switch 73 is turned ON when the digital signal D_{OUT} (HIGH) indicating V_{IN}≧V_{CM} is input, and the switch 74 is turned ON when the digital signal D_{OUT} (LOW) indicating V_{IN}<V_{CM} is input. With this configuration, the input voltage V_{IN} can be restored.

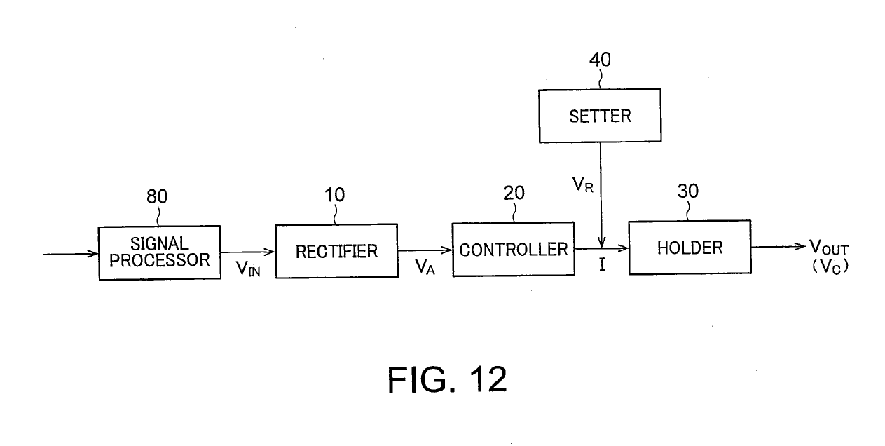

Also, the signal processing circuit according to the present embodiment may include a signal processor 80 as shown in FIG. 12. The signal processor 80 is provided on the input side of the rectifier 10. The signal processor 80 performs arbitrary signal processing such as addition, subtraction, and differential and integral calculus to the input signal (voltage) and inputs the voltage to which the signal processing is performed to the rectifier 10 as the input voltage V_{IN}. An adder circuit, a subtraction circuit, a differentiating circuit, an integrating circuit and the like can be used as the signal processor 80.

### Second Embodiment

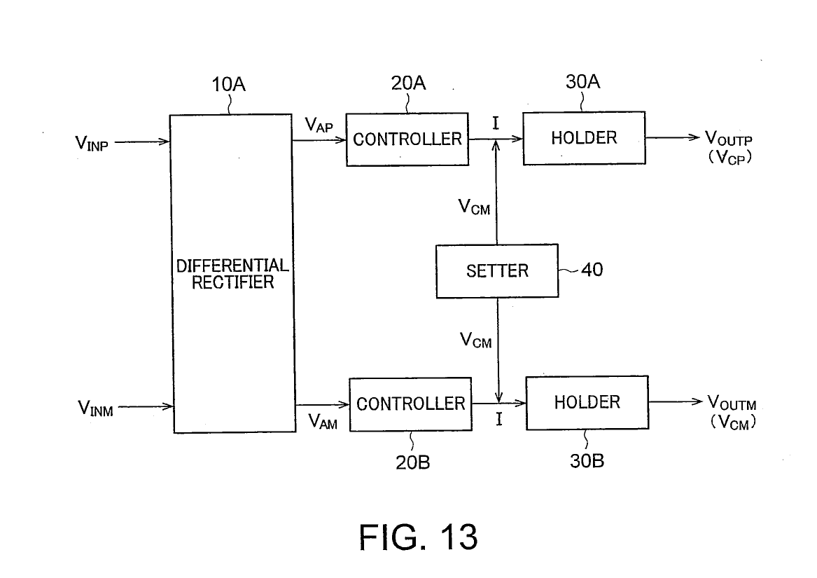

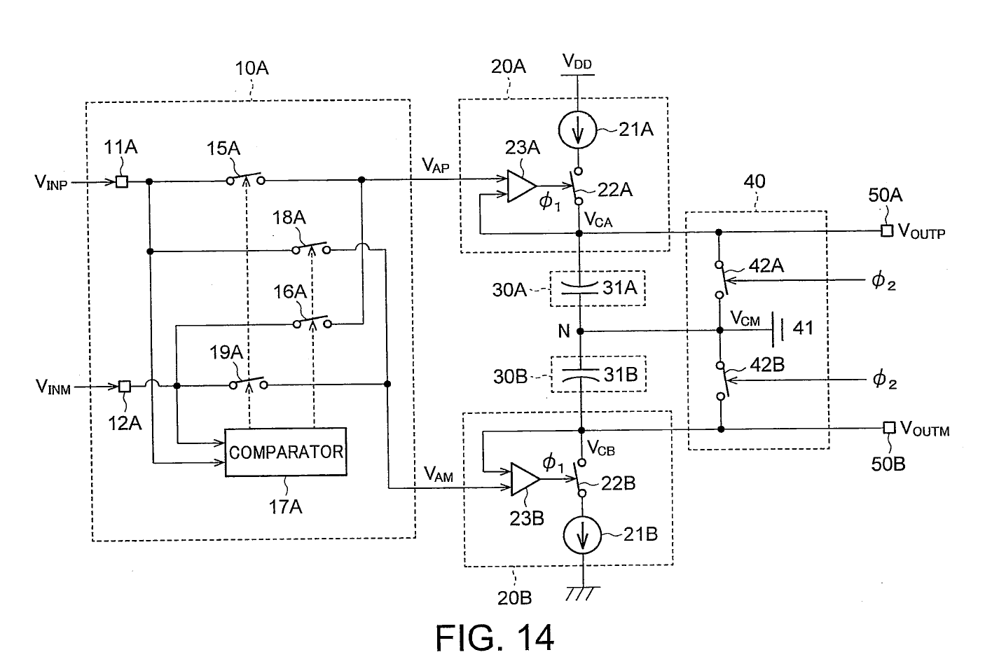

Next, a signal processing circuit according to the second embodiment will be described with reference to FIGS. 13 to 15. Here, FIG. 13 is a block diagram of a function configuration of the signal processing circuit according to the present embodiment. Also, FIG. 14 is a circuit diagram of an exemplary configuration of the signal processing circuit according to the present embodiment. As shown in FIG. 13, the signal processing circuit according to the present embodiment includes a differential rectifier 10A for generating rectified voltages V_{AP} and V_{AM} respectively from input voltages V_{INP} and V_{INM}, holders 30A and 30B for holding an arbitrary voltage, controllers 20A and 20B for respectively controlling hold voltages V_{CP} and V_{CM} held by the holders 30A and 30B based on the rectified voltages V_{AP} and V_{AM}, and a setter 40 for setting the hold voltages V_{CP} and V_{CM} to a predetermined voltage.

The input voltage V_{INP} (first input voltage) and the input voltage V_{INM} (second input voltage) are differentially input to the differential rectifier 10A. The input voltages V_{INP} and V_{INM} are signals in which a reverse phase signal voltage V_{SIG} is superimposed on a common-mode voltage V_{CM}(V_{INP}=V_{CM}+V_{SIG}, V_{INM}=V_{CM}−V_{SIG}). The common-mode voltage V_{CM} is a DC component of the input voltages V_{INP} and V_{INM}, and the signal voltage V_{SIG} is an AC component of the input voltages V_{INP} and V_{INM}. For example, a sampled analog signal (voltage) can be exemplified as the input voltages V_{INP} and V_{INM}.

The differential rectifier 10A generates the rectified voltage V_{AP} (first rectified voltage) by rectifying the input voltage V_{INP}. Also, the differential rectifier 10A generates the rectified voltage V_{AM} (second rectified voltage) by rectifying the input voltage V_{INM}. More particularly, the differential rectifier 10A outputs the voltage, which is equal to or higher than the common-mode voltage V_{CM}, out of the input voltages V_{INP} and V_{INM} as the rectified voltage V_{AP} without rectifying them. Accordingly, the differential rectifier 10A outputs the rectified voltage V_{AP} equal to or higher than the common-mode voltage V_{CM}. That is, the rectified voltage V_{AP} satisfies V_{AP}=V_{INP}=V_{CM}+V_{SIG} when V_{SIG}≧0, and the rectified voltage V_{AP} satisfies V_{AP}=V_{INM}=V_{CM}−V_{SIG} when V_{SIG}<0. Therefore, the rectified voltage V_{AP} generated by the differential rectifier 10A is a voltage in which an absolute value of the signal voltage V_{SIG} is added to the common-mode voltage V_{CM} (V_{AP}=V_{CM}+|V_{SIG}|).

Similarly, the differential rectifier 10A generates the rectified voltage V_{AM} equal to or lower than the common-mode voltage V_{CM} by rectifying the input voltages V_{INP} and V_{INM}. More particularly, the differential rectifier 10A outputs the voltage, which is equal to or lower than the common-mode voltage V_{CM}, out of the input voltages V_{INP} and V_{INM} as the rectified voltage V_{AM} without rectifying them. Accordingly, the differential rectifier 10A outputs the rectified voltage V_{AM} equal to or lower than the common-mode voltage V_{CM}. That is, the rectified voltage V_{AM} satisfies V_{AM}=V_{INM}=V_{CM}−V_{SIG} when V_{SIG}≧0, and the rectified voltage V_{AM} satisfies V_{AM}=V_{INP}=V_{CM}+V_{SIG} when V_{SIG}<0. Therefore, the rectified voltage V_{AM} generated by the differential rectifier 10A is a voltage in which the absolute value of the signal voltage V_{SIG} is subtracted from the common-mode voltage V_{CM} (V_{AM}=V_{CM}−|V_{SIG}|).

As shown in FIG. 14, the differential rectifier 10A includes input terminals 11A and 12A, switches 15A, 16A, 18A, and 19A, and a comparator 17A. The input voltage V_{INP} is input from the input terminal 11A. The input voltage V_{INM} is input from the input terminal 12A.

The switch 15A (sixth switch) is provided between the input terminal 11A and the controller 20A and connects/opens between the input terminal 11A and the controller 20A. The switch 16A (seventh switch) is provided between the input terminal 12A and the controller 20A and connects/opens between the input terminal 12A and the controller 20A. The switch 18A (eighth switch) is provided between the input terminal 11A and the controller 20B and connects/opens between the input terminal 11A and the controller 20B. The switch 19A (ninth switch) is provided between the input terminal 12B and the controller 20B and connects/opens between the input terminal 12B and the controller 20B.

The comparator 17A is connected to the input terminals 11A and 12A, and both the input voltages V_{INP} and V_{INM} are input to the comparator 17A. The comparator 17A compares the magnitude of the input voltage V_{INP} with that of the input voltage V_{INM} and controls opening/closing of the switches 15A, 16A, 18A, and 19A based on the comparison result.

In particular, the comparator 17A turns ON the switches 15A and 19A and turns OFF the switches 16A and 18A when the input voltage V_{INP} is equal to or higher than the input voltage V_{INM} (V_{INP}≧V_{INM}). Accordingly, the rectified voltage V_{AP} output from the differential rectifier 10A becomes the input voltage V_{INP}, and the rectified voltage V_{AM} becomes the input voltage V_{INM} (V_{AP}=V_{INP}, V_{AM}=V_{INM}). Also, the comparator 17A turns OFF the switches 15A and 19A and turns ON the switches 16A and 18A when the input voltage V_{INP} is lower than the input voltage V_{INM} (V_{INP}<V_{INM}). Accordingly, the rectified voltage V_{AP} output from the differential rectifier 10A becomes the input voltage V_{INM}, and the rectified voltage V_{AM} becomes the input voltage V_{INP} (V_{AP}=V_{INM}, V_{AM}=V_{INP}).

The comparator 17A may output the comparison result between the input voltages V_{INP} and V_{INM}, that is, a signal D_{OUT} indicating magnitude relation between the input voltages V_{INP} and V_{INM}. The above-mentioned restorator 70 is connected to each of the output sides of the holders 30A and 30B, and each of the holders 30A and 30B inputs the signal D_{OUT} to the connected restorator 70. Accordingly, the input voltages V_{INP} and V_{INM} can be respectively restored from the hold voltages V_{CA} and V_{CB}.

The holder 30A (first holder) and the holder 30B (second holder) are units for holding the arbitrary voltages. The holders 30A and 30B respectively include capacitive elements 31A and 30B as shown in FIG. 14. A low voltage side of the capacitive element 31A is connected to a high voltage side of the capacitive element 31B, and a connection node N is set to the common-mode voltage V_{CM}. Therefore, the capacitive element 31A can hold the arbitrary voltage between the common-mode voltage V_{CM} and a power-supply voltage V_{DD}, and the capacitive element 31B can hold the arbitrary voltage between a ground voltage and the common-mode voltage V_{CM}.

A side of a power supply (output side) of the capacitive element 31A is connected to the controller 20A and an output terminal 50A (first output terminal) for outputting an output voltage V_{OUTP}. Therefore, the hold voltage V_{CA} held by the holder 30A is output from the output terminal 50A. That is, the hold voltage V_{CA} coincides with the output voltage V_{OUTP} (V_{CA}=V_{OUTP}). Also, a side of the ground (output side) of the capacitive element 31B is connected to the controller 20B and an output terminal 50B for outputting an output voltage V_{OUTM}. Therefore, the output terminal 50B outputs the hold voltage V_{CB} (second hold voltage) held by the holder 30B. That is, the hold voltage V_{CB} coincides with the output voltage V_{OUTM} (V_{CB}=V_{OUTM})

The controller 20A (first controller) is connected between the differential rectifier 10A and the holder 30A. The rectified voltage V_{AP} is input from the differential rectifier 10A to the controller 20A. The controller 20A controls the holder 30A based on the rectified voltage V_{AP} so that the hold voltage V_{CA} becomes equal to the rectified voltage V_{AP}. The controller 20A includes a current source 21A, a switch 22A, and a comparator 23A.

The current source 21A (first current source) supplies the current to the holder 30A and charges the holder 30A. The switch 22A (tenth switch) is provided between the current source 21A and the holder 30A and connects/opens between the current source 21A and the holder 30A. The comparator 23A (first comparator) compares the rectified voltage V_{AP} with the hold voltage V_{CA} and controls the opening/closing of the switch 22A based on the comparison result. That is, a configuration of the controller 20A is similar to that of the controller 20 of a current supply type according to the first embodiment. Therefore, the controller 20A compares the rectified voltage V_{AP} with the hold voltage V_{CA}, and when the rectified voltage V_{AP} is higher than the hold voltage V_{CA}, the controller 20A charges the holder 30A.

The controller 20B (second controller) is connected between the differential rectifier 10A and the holder 30B. The rectified voltage V_{AM} is input from the differential rectifier 10A to the controller 20B. The controller 20B controls the holder 30B based on the rectified voltage V_{AM} so that the hold voltage V_{CB} becomes equal to the rectified voltage V_{AM}. The controller 20B includes a current source 21B, a switch 22B, and a comparator 23B.

The current source 21B (second current source) draws the current from the holder 30B and discharges the holder 30B. The switch 22B (eleventh switch) is provided between the current source 21B and the holder 30B and connects/opens between the current source 21B and the holder 30B. The comparator 23B (second comparator) compares the rectified voltage V_{AM} with the hold voltage V_{CB} and controls the opening/closing of the switch 22B based on the comparison result. That is, a configuration of the controller 20B is similar to that of the controller 20 of a current draw type according to the first embodiment. Therefore, the controller 20B compares the rectified voltage V_{AM} with the hold voltage V_{CB}, and when the rectified voltage V_{AM} is lower than the hold voltage V_{CB}, the controller 20B discharges the holder 30A.

The setter 40 sets the hold voltage V_{CA} of the holder 30A and the hold voltage V_{CB} of the holder 30B to the common-mode voltage V_{CM}. The setter 40 includes a voltage source 41 and switches 42A and 42B. The voltage source 41 supplies the common-mode voltage V_{CM}.

The switch 42A (twelfth switch) is provided between the voltage source 41 and the output side of the capacitive element 31A and connects/opens between the voltage source 41 and the capacitive element 31A. When the switch 42A is ON, the output side of the capacitive element 31A is connected to the voltage source 41 and the hold voltage V_{CA} is set to the common-mode voltage V_{CM}. On the other hand, when the switch 42A is OFF, the voltage source 41 is opened and the hold voltage V_{CA} is controlled by the controller 20A so as to be equal to the rectified voltage V_{AP}.

The switch 42B (thirteenth switch) is provided between the voltage source 41 and the capacitive element 31B and connects/opens between the voltage source 41 and the capacitive element 31B. When the switch 42B is ON, the output side of the capacitive element 31B is connected to the voltage source 41 and the hold voltage V_{CB} is set to the common-mode voltage V_{CM}. On the other hand, when the switch 42B is OFF, the voltage source 41 is opened and the hold voltage V_{CB} is controlled by the controller 20B so as to be equal to the rectified voltage V_{AM}. The opening/closing of the switches 42A and 42B is controlled by the same control signal φ₂. Therefore, the opening/closing of the switch 42A is synchronized with that of the switch 42B.

According to the present embodiment, with the configuration in which the signal processing circuit differentially inputs and outputs, the variation of the common-mode voltage V_{CM} included in the input voltages V_{INP} and V_{INM} and the influence by a power supply noise and the like can be reduced. Also, since the differential rectifier 10A can include a comparator 17A and four switches, the configuration of the signal processing circuit can be simplified and the circuit size can be reduced. At the same time, the power consumption required for rectifying the input voltages V_{INP} and V_{INM} can be reduced.

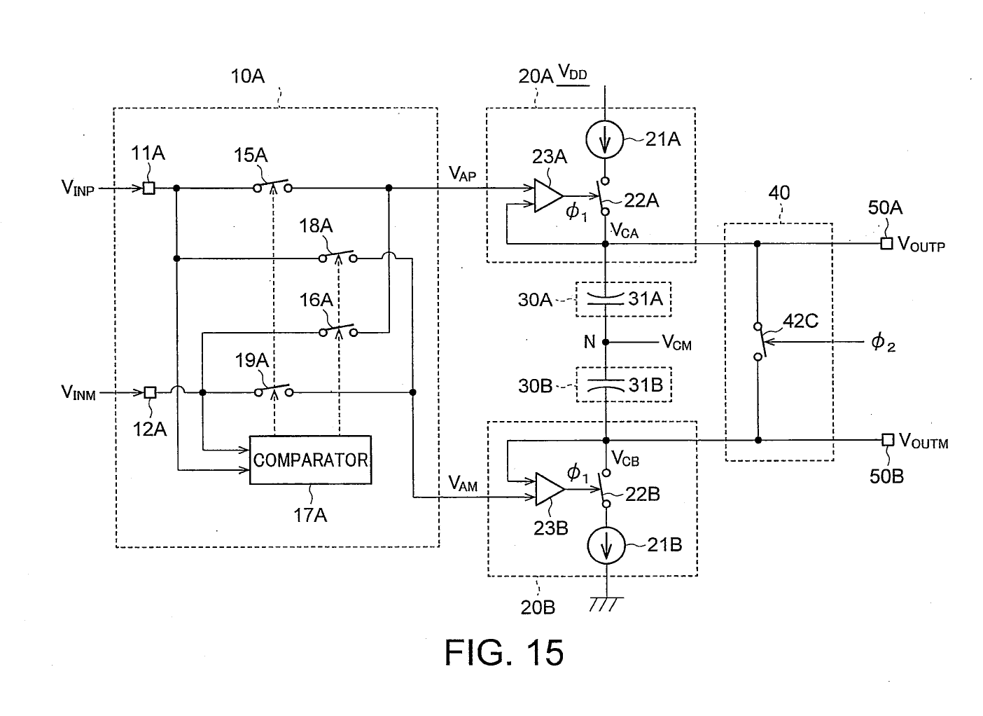

The setter 40 can include a switch 42C (fourteenth switch) which connects/opens between the output side of the capacitive element 31A and the output side of the capacitive element 31B as shown in FIG. 15. When the switch 42C is ON, the capacitive elements 31A and 31B are short-circuited. Accordingly, the common-mode voltage V_{CM} which is a voltage of the node N is output as the output voltages V_{OUTP} and V_{OUTM}. With this configuration, the setter 40 can be simplified and a circuit size can be further reduced.

### Third Embodiment

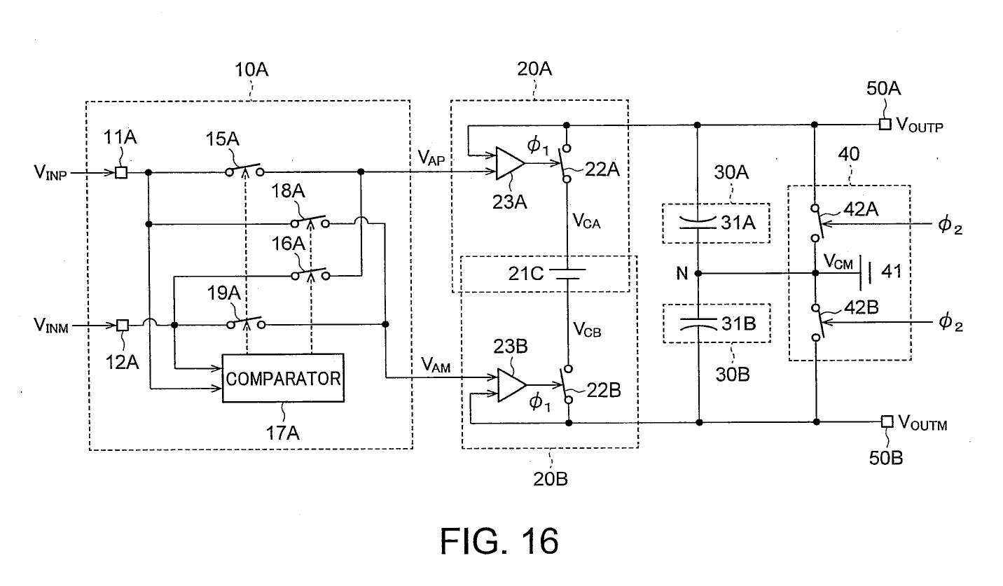

Next, a signal processing circuit according to the third embodiment will be described with reference to FIG. 16. Here, FIG. 16 is a circuit diagram of an exemplary configuration of the signal processing circuit according to the present embodiment. As shown in FIG. 16, the signal processing circuit according to the present embodiment includes a differential rectifier 10A, controllers 20A and 20B, holders 30A and 30B, and a setter 40. Configurations of the differential rectifier 10A, the holders 30A and 30B, and the setter 40 are similar to those of the second embodiment.

In the present embodiment, the controllers 20A and 20B include a secondary battery 21C in common instead of the current sources 21A and 21B in the second embodiment. That is, the controller 20A includes the secondary battery 21C, a switch 22A, and a comparator 23A, and the controller 20B includes the secondary battery 21C, a switch 22B, and a comparator 23B. For example, a capacitive element in which a predetermined voltage is charged can be used as the secondary battery 21C.

In the present embodiment, when the switches 22A and 22B are ON, a current discharged from the capacitive element 31B is charged to the capacitive element 31A via the secondary battery 21C. Therefore, the signal processing circuit according to the present embodiment can realize operation similar to that of the second embodiment.

With this configuration, configurations of the controllers 20A and 20B can be simplified and a circuit size can be reduced. Also, since current sources of the controllers 20A and 20B are not necessary, power can be reduced.

The signal processing circuit according to each embodiment above can be applied to a pipeline A/D converter and a successive comparison A/D converter. In this case, it is preferable that a sampled single-phase input analog signal be input to the signal processing circuit according to the first embodiment as the input voltage V_{IN}. Also, it is preferable that a sampled differential input analog signal be input to the signal processing circuit according to the second and third embodiments as each input voltages V_{INP} and V_{INM}. The power consumption of the A/D converter can be reduced by having the signal processing circuit according to the embodiments described above. Also, the circuit size can be reduced, and the A/D converter can be miniaturized.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A signal processing circuit comprising:
a rectifier to generate a rectified voltage by rectifying an input voltage in which a signal voltage is superimposed on a common-mode voltage;
a holder to hold a voltage;
a controller to control the holder so as to hold a voltage according to the rectified voltage generated by the rectifier; and
a setter to set the voltage held by the holder to a predetermined voltage at predetermined time intervals.

2. The circuit according to claim 1, wherein
the rectifier generates a voltage in which an absolute value of the signal voltage is added to the common-mode voltage or a voltage in which the absolute value of the signal voltage is subtracted from the common-mode voltage as the rectified voltage.

3. The circuit according to claim 1, wherein
the rectifier includes
an input terminal to which the input voltage is input,
an amplifier to amplify the common-mode voltage,
a subtraction circuit to subtract the input voltage from the common-mode voltage amplified by the amplifier,
a first switch to connect and open between the input terminal and the controller,
a second switch to connect and open between the subtraction circuit and the controller, and
a comparator to control the first and second switches based on a comparison result between the input voltage and the common-mode voltage.

4. The circuit according to claim 1, wherein
the rectifier generates a signal indicating a comparison result between the input voltage and the common-mode voltage.

5. The circuit according to claim 4, further comprising;
a restorator to restore the input voltage from an output voltage based on the signal generated by the rectifier.

6. The circuit according to claim 1, wherein
the holder includes a capacitive element.

7. The circuit according to claim 1, wherein
the setter includes a voltage source to supply a predetermined voltage, and
a third switch to connect and open between the voltage source and the holder.

8. The circuit according to claim 1, further comprising:
a sampler to sample an analog signal, wherein
a voltage sampled by the sampler is input to the rectifier as the input voltage.

9. The circuit according to claim 1, further comprising:
a signal processor to perform predetermined signal processing to the input voltage, wherein
a voltage performed the predetermined signal processing by the signal processor is input to the rectifier as the input voltage.

10. The circuit according to claim 1, wherein
the controller compares the rectified voltage with the voltage held by the holder and increases the voltage held by the holder when the rectified voltage is higher than the voltage held by the holder.

11. The circuit according to claim 10, wherein
the controller includes
a current source to charge the holder,
a fourth switch to connect and open between the current source and the holder, and
a comparator to control the fourth switch based on a comparison result between the rectified voltage and the voltage held by the holder.

12. The circuit according to claim 1, wherein
the controller compares the rectified voltage with the voltage held by the holder and decreases the voltage held by the holder when the rectified voltage is lower than the voltage held by the holder.

13. The circuit according to claim 12, wherein
the controller includes
a current source to discharge the holder,
a fifth switch to connect and open between the current source and the holder, and
a comparator to control the fifth switch based on a comparison result between the rectified voltage and the voltage held by the holder.

14. A signal processing circuit comprising:
a differential rectifier to generate first and second rectified voltages by rectifying first and second input voltages in which a signal voltage is superimposed on a common-mode voltage;
a first holder to hold a voltage;
a first controller to control the first holder so as to hold a voltage according to the first rectified voltage generated by the differential rectifier;
a second holder to hold a voltage;
a second controller to control the second holder so as to hold a voltage according to the second rectified voltage generated by the differential rectifier; and
a setter to set the voltages held by the first and second holders to predetermined voltages at predetermined time intervals.

15. The circuit according to claim 14, wherein
the differential rectifier generates a voltage in which an absolute value of the signal voltage is added to the common-mode voltage as the first rectified voltage and generates a voltage in which the absolute value of the signal voltage is subtracted from the common-mode voltage as the second rectified voltage.

16. The circuit according to claim 14, wherein
the differential rectifier includes
a first input terminal to which the first input voltage is input,
a second input terminal to which the second input voltage is input,
a sixth switch to connect and open between the first input terminal and the first controller,
a seventh switch to connect and open between the second input terminal and the first controller,
an eighth switch to connect and open between the first input terminal and the second controller,
a ninth switch to connect and open between the second input terminal and the second controller, and
a comparator to control the sixth, seventh, eighth, and ninth switches based on a comparison result between the first input voltage and the second input voltage.

17. The circuit according to claim 14, wherein
the first controller compares the first rectified voltage with the voltage held by the first holder and charges the first holder when the first rectified voltage is higher than the voltage held by the first holder, and
the second controller compares the second rectified voltage with the voltage held by the second holder and discharges the second holder when the second rectified voltage is lower than the voltage held by the second holder.

18. The circuit according to claim 14, wherein
the first controller includes
a first current source to charge the first holder,
a tenth switch to connect and open between the first current source and the first holder, and
a first comparator to control the tenth switch based on a comparison result between the first rectified voltage and the voltage held by the first holder, and
the second controller includes
a second current source to discharge the second holder,
an eleventh switch to connect and open between the second current source and the second holder, and
a second comparator to control the eleventh switch based on a comparison result between the second rectified voltage and the voltage held by the second holder.

19. The circuit according to claim 18, wherein
the first and second current sources share the secondary battery.

20. The circuit according to claim 14, wherein
the setter includes
a voltage source to supply a predetermined voltage,
a twelfth switch to connect and open between the voltage source and the first holder, and
a thirteenth switch to connect and open between the voltage source and the second holder.

21. The circuit according to claim 14, wherein
the setter sets the voltages held by the first and second holder to the common-mode voltage.

22. The circuit according to claim 14, wherein
the setter includes a fourteenth switch to connect and open between the first holder and the second holder.

23. An A/D converter comprising:
the circuit according to claim 1.
